(19) United States
(12) Patent Application Publication
(10) Pub. No.: US 2026/0033195 A1
(43) Pub. Date: Jan. 29, 2026

(54) DISPLAY PANEL

(71) Applicant: HKC CORPORATION LIMITED, SHENZHEN (CN)

(72) Inventors: Dongmei WEI, SHENZHEN (CN); Lidan YE, SHENZHEN (CN)

(73) Assignee: HKC CORPORATION LIMITED, SHENZHEN (CN)

(21) Appl. No.: 19/248,579

(22) Filed: Jun. 25, 2025

(30) Foreign Application Priority Data
Jul. 23, 2024 (CN) 202410996864.7

(51) Int. Cl. H10K 59/131; H10K 59/127

(52) U.S. Cl. CPC H10K 59/1315; H10K 59/1275

(57) ABSTRACT

A display panel is disclosed. The display panel includes a glass substrate, multiple light-emitting units, multiple first bonding portions, multiple second bonding portions, an auxiliary electrode, and a silicon-based driving substrate. The glass substrate includes multiple first conductive vias and multiple second conductive vias extending from the first surface to the second surface. The first bonding portions are electrically connected to the corresponding anode electrodes through the corresponding first conductive vias. The second bonding portions are electrically connected to the cathode electrodes through the corresponding second conductive vias. The auxiliary electrode is disposed on the second surface of the glass substrate, covering the second bonding portions and contacting the second bonding portions. The silicon-based driving substrate includes multiple first bonding electrodes that are bonded to the multiple first bonding portions in one-to-one correspondence, and at least one second bonding electrode that is bonded to the auxiliary electrode.

### CROSS-REFERENCE TO RELATED APPLICATIONS

This application claims priority to Chinese Patent Application No. 202410996864.7, filed on Jul. 23, 2024, the content of which is herein incorporated by reference in its entirety.

### TECHNICAL FIELD

The present disclosure relates to the technical field of displays, and in particular to a display panel.

### BACKGROUND

A monocrystalline silicon driving backplanes is a driving substrate formed using semiconductor devices as driving units, which are formed through Complementary Metal Oxide Semiconductor (CMOS) processes. Compared with the conventional Active-matrix organic light-emitting diode (AMOLED) panels that use amorphous silicon, microcrystalline silicon, or low-temperature polysilicon thin-film transistors as backplanes, monocrystalline silicon driving backplanes have a higher carrier mobility. Therefore, silicon-based organic light-emitting diode (OLED) display panels currently represent the display type with optimal performance applied in products in the AR/VR field.

Currently in silicon-based OLED display panels, traditionally externally bonded display chips are integrated into the silicon driving backplane. The preparing process involves evaporating and depositing OLED light-emitting devices on the silicon-based driving substrate. Specifically, first depositing anode electrodes, then fabricating a pixel defining layer, followed by sequentially depositing organic light-emitting layers and cathode electrodes. In this way, pixel units with smaller sizes can be prepared, which achieves a display fineness that exceeds the retinal level and have many advantages such as high resolution, high integration degree, low power consumption, small volume, and light weight.

However, directly evaporating and depositing OLED light-emitting devices on silicon-based driving substrates may have an impact on the silicon-based driving circuits, resulting in the damage and incapability of the driving circuit, which thus increases the cost.

### SUMMARY

A technical solution adopted in the present disclosure is to provide a display panel, including:
a glass substrate, including a first surface and a second surface opposite to each other and having a plurality of conductive vias extending from the first surface to the second surface; the plurality of conductive vias including a plurality of first conductive vias and a plurality of second conductive vias;
a plurality of light-emitting units, disposed on the first surface of the glass substrate; each of the light-emitting units including an anode electrode, an organic light-emitting layer, and a cathode electrode sequentially stacked in a direction away from the glass substrate;
a plurality of first bonding portions, each of the first bonding portions being at least partially disposed within a corresponding first conductive via of the first conductive vias and being electrically connected to a corresponding anode electrode through the corresponding first conductive via;
a plurality of second bonding portions, each of the second bonding portions being at least partially disposed within a corresponding second conductive via of the second conductive vias and being electrically connected to a corresponding cathode electrode through the corresponding second conductive via;
an auxiliary electrode, disposed on the second surface of the glass substrate, covering the second bonding portions, and being in contact with the second bonding portions; and
a silicon-based driving substrate, disposed on the second surface of the glass substrate and including a plurality of first bonding electrodes and at least one second bonding electrode; the plurality of first bonding electrodes being aligned and bonded to the plurality of first bonding portions in one-to-one correspondence; the at least one second bonding electrode being bonded to the auxiliary electrode.

Another technical solution adopted in the present disclosure is to provide a display panel, including:
a glass substrate, comprising a plurality of first bonding portions and a plurality of second bonding portions, wherein each of the first bonding portions is electrically connected to a corresponding anode electrode, and each of the second bonding portions is electrically connected to a corresponding cathode electrode;
an auxiliary electrode, being in contact with the second bonding portions; and
a silicon-based driving substrate, aligned and bonded to the glass substrate, wherein the silicon-based driving substrate comprises a plurality of first bonding electrodes and at least one second bonding electrode; the plurality of first bonding electrodes are aligned and bonded to the plurality of first bonding portions in one-to-one correspondence; the at least one second bonding electrode is bonded to the second bonding portions through the auxiliary electrode.

Another technical solution adopted in the present disclosure is to provide a display panel, including:
a glass substrate, comprising a plurality of first bonding portions and a plurality of second bonding portions, wherein each of the first bonding portions is electrically connected to a corresponding anode electrode, and each of the second bonding portions is electrically connected to a corresponding cathode electrode;
a plurality of light-emitting units, disposed on the glass substrate, wherein each of the light-emitting units comprises an anode electrode, an organic light-emitting layer, and a cathode electrode sequentially stacked on the glass substrate, a corresponding anode electrode is electrically connected to a corresponding one of the first bonding portions, and a corresponding cathode electrode is electrically connected to a corresponding one of the second bonding portions; an auxiliary electrode, being in contact with the second bonding portions; and
a silicon-based driving substrate, aligned and bonded to the glass substrate, wherein the silicon-based driving substrate comprises a plurality of first bonding electrodes and at least one second bonding electrode; the plurality of first bonding electrodes are aligned and bonded to the plurality of first bonding portions in one-to-one correspondence; the at least one second bonding electrode is bonded to the second bonding portions through the auxiliary electrode.

### BRIEF DESCRIPTION OF THE DRAWINGS

FIG. 1 is a schematic structural view of a display panel according to first embodiments of the present disclosure.

FIG. 2 is a bottom view of the glass substrate in the display panel shown in FIG. 1.

FIG. 3 is a schematic structural view in which the auxiliary electrode is disposed on the glass substrate shown in FIG. 2.

FIG. 4 is a schematic structural view of the silicon-based driving substrate in the display panel shown in FIG. 1.

FIG. 5a is a partial enlarged view of area A in the display panel shown in FIG. 1.

FIG. 5b is a schematic structural view of the structure shown in FIG. 5a without the auxiliary electrode and the second bonding electrode.

FIG. 6 is a schematic structural view of a display panel according to second embodiments of the present disclosure.

FIG. 7 is a bottom view of the display panel shown in FIG. 6 without the silicon-based driving substrate.

FIG. 8 is a bottom view of a display panel without the silicon-based driving substrate according to another embodiment.

FIG. 9 is a schematic flow chart of a preparing method for a display panel according to embodiments of the present disclosure.

FIG. 10 is a schematic structural view after operation S1 is performed.

FIG. 11 is a schematic structural view after operation S2 is performed.

FIG. 12 is a specific flow chart of operation S2.

FIG. 13 is a schematic structural view after operation S21 is performed.

FIG. 14 is a schematic structural view after operation S22 is performed.

FIG. 15 is a schematic structural view after operation S23 is performed.

FIG. 16 is a schematic structural view after operation S24 is performed.

FIG. 17 is a schematic structural view after operation S25 is performed.

FIG. 18 is a schematic structural view after operation S26 is performed.

FIG. 19 is a schematic structural view after operation S3 is performed.

FIG. 20a is a schematic structural view after operation S4 is performed.

FIG. 20b is a schematic structural view of which an insulating layer is disposed on the structure shown in FIG. 20a.

FIG. 20c is a schematic structural view of which an insulating layer is disposed on the second surface according to another embodiment.

FIG. 21 is a schematic structural view after operation S5 is performed.

FIG. 22 is a schematic structural view after operation S6 is performed.

### DETAILED DESCRIPTIONS

Technical solutions of the embodiments of the present disclosure will be clearly and comprehensively described as shown in the accompanying drawings. Obviously, the embodiments described herein are only a part of, but not all of, the embodiments of the present disclosure. Based on the embodiments in the present disclosure, all other embodiments obtained by a person of ordinary skill in the art without any creative work shall fall within the scope of the present disclosure.

Terms “first”, “second”, and “third” in the embodiments of the present disclosure are only used for descriptive purposes, and cannot be understood as indicating or implying relative importance or implicitly indicating the number of indicated technical features. Therefore, features defined with “first”, “second”, and “third” may explicitly or implicitly comprise at least one of the features. In the description of the present disclosure, “a plurality of” means at least two, such as two, three, etc., unless specifically defined otherwise. In the embodiments of the present disclosure, all directional indications (such as up, down, left, right, front, back, etc.) are only used to explain the relative position relationship, motion, etc. between components in a specific attitude (as shown in the FIG.). If the specific attitude changes, the directional indication will change accordingly. In addition, terms “including”, “having”, and any variations thereof are intended to cover non-exclusive inclusions. For example, a process, method, system, product, or device that comprises a series of operations or units is not limited to the listed operations or units, but optionally comprises unlisted operations or units, or optionally also comprises other operations or units inherent to these processes, methods, products or equipment.

The reference to “an embodiment” means that a specific feature, structure or characteristic described in connection with an embodiment may be comprised in at least one embodiment of the present disclosure. The appearance of “an embodiment” in various places in the specification does not necessarily refer to the same embodiment, nor is it an independent or alternative embodiment mutually exclusive with other embodiments. It is understood explicitly and implicitly by those skilled in the art that the embodiments described in the present disclosure can be combined with other embodiments.

The present disclosure will be described in detail below with reference to the accompanying drawings and embodiments.

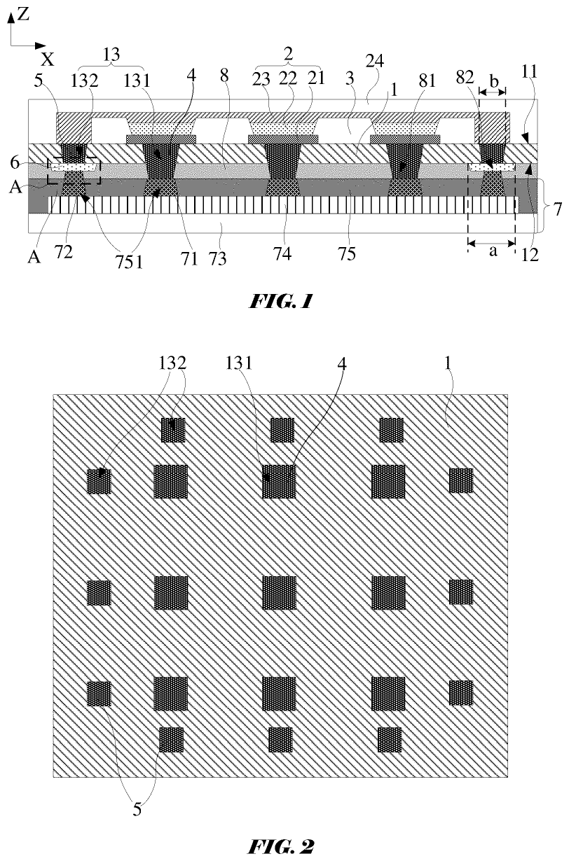

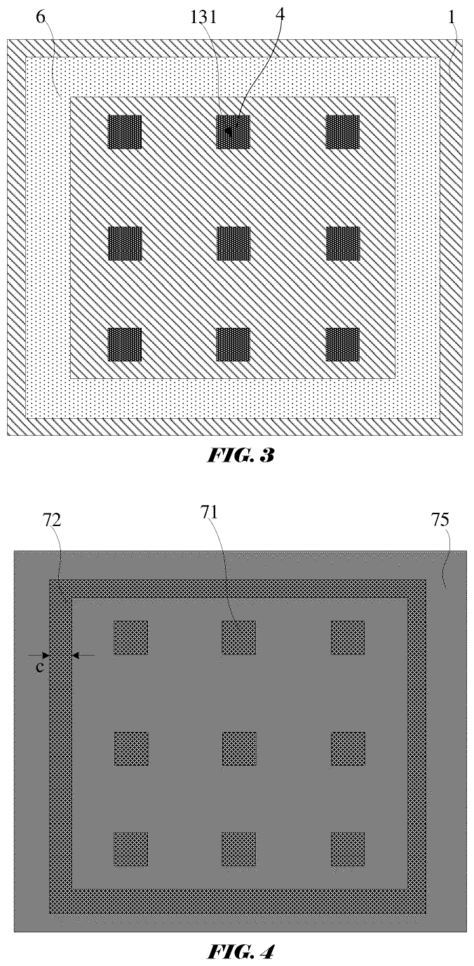

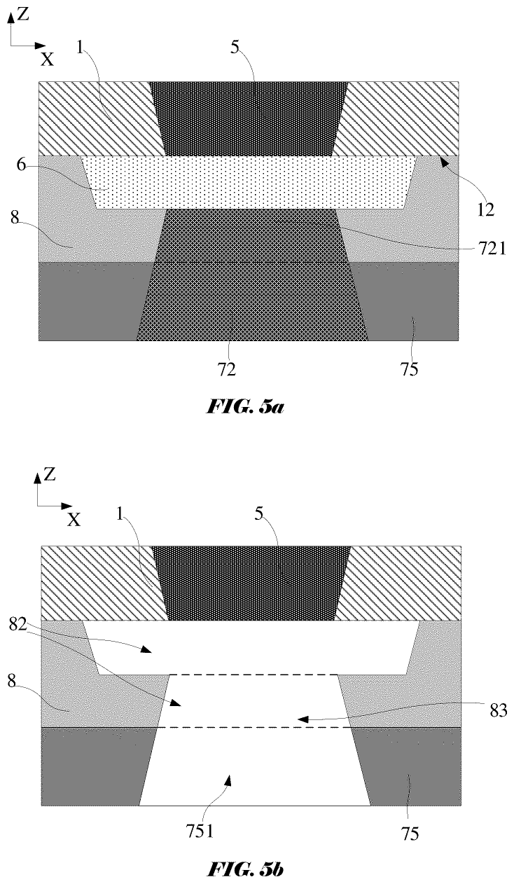

As shown in FIG. 1-FIG. 5b, FIG. 1 is a schematic structural view of a display panel according to first embodiments of the present disclosure; FIG. 2 is a bottom view of the glass substrate in the display panel shown in FIG. 1; FIG. 3 is a schematic structural view in which the auxiliary electrode is disposed on the glass substrate shown in FIG. 2; FIG. 4 is a schematic 20) structural view of the silicon-based driving substrate in the display panel shown in FIG. 1; FIG. 5a is a partial enlarged view of area A in the display panel shown in FIG. 1; FIG. 5b is a schematic structural view of the structure shown in FIG. 5a without the auxiliary electrode and the second bonding electrode. The present disclosure provides a display panel, which may be an OLED display panel. The display panel may include a glass substrate 1, multiple light-emitting units 2, multiple first bonding portions 4, multiple second bonding portions 5, an auxiliary electrode 6, and a silicon-based driving substrate 7.

The glass substrate 1 may include a first surface 11 and a second surface 12 opposite to each other. The glass substrate 1 may have multiple conductive vias 13 extending from the first surface 11 to the second surface 12. Specifically, laser-induced etching technology may be used to form vias in the glass substrate 1, then the vias may be filled with conductive materials to form the conductive vias 13, so that an electrical connection may be achieved between the first surface 11 and second surface 12 of the glass substrate 1 through the conductive vias 13. A diameter of the conductive via 13 may be between 50 micrometers and 100 micrometers. It should be understood that too small spacing between adjacent conductive vias 13 may affect the structural strength of the glass substrate 1, causing damage to the glass substrate 1, while too large spacing may reduce the density of conductive vias 13. Therefore, the spacing between adjacent conductive vias 13 may be between 50 micrometers and 150 micrometers. Specifically, the multiple conductive vias 13 may include multiple first conductive vias 131 and multiple second conductive vias 132.

The multiple light-emitting units 2 may be disposed on the first surface 11 of the glass substrate 1. Each of the light-emitting units 2 may include an anode electrode 21, an organic light-emitting layer 22, and a cathode electrode 23, which sequentially stacked in a direction away from the glass substrate 1. Specifically, a pixel defining layer 3 may be further disposed on the first surface 11 of the glass substrate 1. The pixel defining layer 3 may protrude from the glass substrate 1 and enclose to form multiple pixel accommodation regions (not shown), in which the multiple light-emitting units 2 may be respectively disposed. The multiple pixel accommodation regions may be arranged in one-to-one correspondence with the multiple first conductive vias 131.

An anode electrode 21 may be disposed on the surface of the glass substrate 1 exposed with respect to the pixel accommodation region. A pixel defining layer 3 may cover edges of the anode electrodes 21 to prevent the anode electrodes 21 of adjacent light-emitting units 2 from contacting with each other, which may lead to signal crosstalk. An organic light-emitting layer 22 may be disposed on a surface of an anode electrode 21 away from the glass substrate 1, and a cathode electrode 23 may be disposed on a surface of the organic light-emitting layer 22 away from the anode electrode 21, covering the organic light-emitting layers 22 of multiple light-emitting units 2 to form a common cathode at the whole surface. An anode electrode 21 may transmit anode driving signals, and a cathode electrode 23 may transmit cathode driving signals to an organic light-emitting layer 22 to drive the organic light-emitting layer 22 for light emission.

In some embodiments, the light-emitting units 2 may include those ones with different emission colors, such as red light-emitting unit 2, green light-emitting unit 2, and blue light-emitting unit 2, to achieve color display. Specifically, the emission color may be determined by an organic light-emitting layer 22. In some embodiments, in another embodiments, the light-emitting units 2 may also be light-emitting units 2 of the same color, e.g., white, red, green, blue, or others, which may be set according to practical needs. For example, if the light-emitting units 2 emit white light, the brightness of the light-emitting units 2 may be controlled to achieve grayscale display. Additionally, a color filter layer may be added above the light-emitting units 2 to achieve color display. For example, if the light-emitting units 2 emit blue light, a red quantum dot layer may be added above some of the light-emitting units 2, and a green quantum dot layer may be added above some of the light-emitting units 2, so as to achieve color display.

Each first bonding portion 4 may be at least partially disposed in a corresponding first conductive via 131, and each first bonding portion 4 may be electrically connected to an anode electrode 21 through the corresponding first conductive via 131, such that an anode driving signal may be transmitted to the anode electrode 21 of a corresponding light-emitting unit 2 through the first conductive via 131. Each second bonding portion 5 may be at least partially disposed in a corresponding second conductive via 132, and each second bonding portion 5 may be electrically connected to a cathode electrode 23 through a corresponding second conductive via 132, such that the cathode driving signal may be transmitted to the cathode electrode 23 of a light-emitting unit 2 through the second conductive via 132. In some embodiments, each of the second bonding portions 5 may extend from a first surface of the glass substrate 1 to a second surface 12 of the glass substrate 1 in the stacking direction Z, and the each of the first bonding portions 4 may extend from the first surface 11 beyond the second surface 12 in the stacking direction, and the first surface 11 may be opposite to the second surface 12.

An auxiliary electrode 6 may be disposed on the second surface 12 of the glass substrate 1 and may contact with the second bonding portions 5 to provide additional current channels. A part of a surface of the auxiliary electrode 6 close to the glass substrate 1 may correspond multiple third vias 82 and cover the second bonding portions 5, while another part of the surface may contact with the second surface 12 of the glass substrate 1. In some embodiments, a surface of the auxiliary electrode 6 may be substantially flush with the second surface 12 of the glass substrate 1 and be in contact with the second bonding portions 5.

A silicon-based driving substrate 7 may be disposed at a side of the second surface 12, and the silicon-based driving substrate 7 may include multiple first bonding electrodes 71 and at least one second bonding electrode 72. The multiple first bonding electrodes 71 may be aligned and bonded to the multiple first bonding portions 4 in one-to-one correspondence. A silicon-based driving substrate 7 may transmit the anode driving signal to an anode electrode 21 through the first bonding electrodes 71 and the first bonding portions 4. The at least one second bonding electrode 72 may be bonded to an auxiliary electrode 6. The silicon-based driving substrate 7 may transmit the cathode driving signal to the cathode electrodes 23 through the second bonding electrodes 72, the auxiliary electrode 6, and the second bonding portions 5, so as to control light emission of the light-emitting unit 2. In some embodiments, a thickness of each of the second bonding portions 5, a corresponding second bonding electrode 72, and the auxiliary electrode 6 in a stacking direction Z in which the glass substrate 1 and the silicon-based driving substrate 7 may be stacked may be equal to a thickness of each of the first bonding portions 4 and a corresponding first bonding electrode 71 in the stacking direction Z. A thickness of the each of the second bonding portions 5 may be less than a thickness of the each of the first bonding portions 4. A thickness of the corresponding second bonding electrode 71 may be greater than a thickness of the corresponding first bonding electrode 72.

As the light-emitting units 2, the first bonding portions 4, and the second bonding portions 5 may be arranged on the two opposite surfaces of the glass substrate 1 respectively, the first bonding portions 4 may be contacted with and electrically connected with the anode electrodes 21 of the corresponding light-emitting units 2 through the first conductive vias 131, and the second bonding portions 5 may be contacted with and electrically connected with the cathode electrodes 23 of the light-emitting units 2 through the second conductive vias 132. Thus, after the first bonding portions 4 and the second bonding portions 5 may be bonded to the first bonding electrodes 71 and the second bonding electrodes 72 of the silicon-based driving substrate 7 respectively, the electrical coupling between the light-emitting units 2 and the silicon-based driving substrate 7 may be achieved, enabling the silicon-based driving substrate 7 to drive the light-emitting units 2 to emit light. In this way, the light-emitting units 2 first may be fabricated on the glass substrate 1 and then bonded to the silicon-based driving substrate 7, rather than the light-emitting units 2 being directly fabricated on the silicon-based driving substrate 7, thereby avoiding the problem of damaging to pixel driving circuits and then resulting in a reduction in the product yield which is caused by directly fabricating the light-emitting units 2 on the silicon-based driving substrate 7.

Further, as an auxiliary electrode 6 may be arranged on the second surface 12 of the glass substrate 1 and the second bonding portions 5 may be electrically connected to the second bonding electrodes 72, more current channels may be provided, thereby reducing a resistance 20) between the second bonding portions 5 and the second bonding electrodes 72, effectively decreasing cathode signal load, and consequently reducing cathode signal delay. In some embodiments, each of the at least one second bonding electrode 72 and a corresponding second bonding portion 5 of the second bonding portions 5 may be located in a same line of a stacking direction Z in which the glass substrate 1 and the silicon-based driving substrate 7 may be stacked, such that the at least one second bonding electrode 72 may be aligned and bonded to the second bonding portions 5 through the auxiliary electrode 6.

As shown in FIG. 1 and FIG. 2, in specific embodiments, the multiple second conductive vias 132 may be spaced apart and arranged around the multiple first conductive vias 131, and the multiple second bonding portions 5 may be arranged around the multiple first bonding portions 4, such that electrical contact points surrounding the multiple light-emitting units 2 may be formed on the entire cathode electrode 23. Consequently, the silicon-based driving substrate 7 may transmit cathode driving signals to the cathode electrode 23 through the circumferentially arranged the multiple second bonding portions 5 and the multiple second conductive vias 132, thereby improving the uniformity of the cathode driving signals and reducing voltage drop. In some embodiments, the glass substrate 1 may include multiple first bonding portions 4 and multiple second bonding portions 5. Each of the first bonding portions 4 may be electrically connected to a corresponding anode electrode 21. Each of the second bonding portions 5 may be electrically connected to a corresponding cathode electrode 23. An auxiliary electrode 6 may be in contact with the second bonding portions 5. A silicon-based driving substrate 7 may be aligned and bonded to the glass substrate 1. The silicon-based driving substrate 7 may include multiple first bonding electrodes 71and at least one second bonding electrode 72. The multiple first bonding electrodes 71 may be aligned and bonded to the plurality of first bonding portions 4 in one-to-one correspondence. The at least one second bonding electrode 72 may be bonded to the second bonding portions 5 through the auxiliary electrode 6. As shown in FIG. 2, the first bonding portions 4 may be arranged in an array, and the second bonding portions 5 are arranged around the array. Every two adjacent one of the first bonding portions 4 in a direction of the array may have a same distance, and each of the second bonding portions 5 may correspond to one of the first bonding portions 4.

As shown in FIG. 3, an auxiliary electrode 6 may be an annular auxiliary electrode arranged around the multiple first conductive vias 131, and the annular auxiliary electrode 6 may cover the multiple second bonding portions 5, thereby further increasing the current channels provided by an auxiliary electrode 6 and further reducing the resistance between the second bonding portions 5 and the second bonding electrodes 72. Specifically, a width a of an annular auxiliary electrode 6 may be greater than an aperture b of a second conductive via 132, and a part of the surface of the annular auxiliary electrode 6 towards the glass substrate 1 may cover the second bonding portions 5, thereby increasing a contact area between the annular auxiliary electrode 6 and the second bonding portions 5, providing more conductive channels between the annular auxiliary electrode 6 and the second bonding portions 5, allowing current to pass more easily, and further reducing the resistance between the annular auxiliary electrode 6 and the second bonding portions 5. A part of a surface of an annular auxiliary electrode 6 towards the silicon-based driving substrate 7 may cover at least part of the second bonding electrode 72 to ensure electrical connection between the second bonding portions 5 and a corresponding second bonding electrode 72. In some embodiments, an auxiliary electrode 6 may be an annular auxiliary electrode to cover the second bonding portions 5 and be in contact with the second bonding portions 5.

Those skilled in the art will understand that if the second bonding portions 5 may be directly and misalignedly bonded to the second bonding electrodes 72, a contact area between the second bonding portions 5 and the second bonding electrodes 72 may be small, and current may only be transmitted through locations at which the second bonding portions 5 and the second bonding electrodes 72 may be contacted, resulting in fewer conductive channels and increased resistance there between. As an annular auxiliary electrode 6 may be arranged between the second bonding portions 5 and the second bonding electrodes 72 and the annular auxiliary electrode 6 respectively may cover larger areas of both the second bonding portions 5 and the second bonding electrodes 72 compared with original contact areas, the conductive channels between the second bonding electrode 72 and the annular auxiliary electrode 6 may be increased as well as the conductive channels between the annular auxiliary electrode 6 and the second bonding portions 5, thereby reducing the resistance.

As shown in FIG. 1 and FIG. 4, in specific embodiments, a second bonding electrode 72 may be an annular bonding electrode, and a width c of the annular bonding electrode may be less than a width a of an annular auxiliary electrode 6, with the annular auxiliary electrode 6 covering the annular bonding electrode. Thus, this may increase the contact area between a second bonding electrode 72 and an annular auxiliary electrode 6 and further reduce the resistance therebetween. Understandably, compared with multiple individual bonding electrodes, the annular bonding electrode may provide a larger contact area with the annular conductive adhesive layer, enabling more conductive channels between them and allowing current to pass more easily, thereby further reducing the resistance between the annular auxiliary electrode 6 and the second bonding electrode 72. In some embodiments, the at least one second bonding electrode 72 may be an annular bonding electrode. The annular bonding electrode may be covered by the annular auxiliary electrode 6. A size of the annular bonding electrode may be less than a size of the annular auxiliary electrode 6 such that the annular bonding electrode may be covered by the annular auxiliary electrode 6.

As shown in FIG. 5a, in specific embodiments, a surface of a second bonding portion 5 close to an auxiliary electrode 6 may be substantially flush with the second surface 12 of the glass substrate 1, and the auxiliary electrode 6 may cover the multiple second conductive vias 132, so as to make the auxiliary electrode 6 flat, facilitating the bonding between the auxiliary cathode and a second bonding electrode 72. It may also avoid a situation in which a second bonding portion 5 is squeezed to fall after the glass substrate 1 and the silicon-based driving substrate 7 may be bonded.

It will be understood that if a surface of a second bonding portion 5 close to an auxiliary electrode 6 may protrude from the second surface 12 of the glass substrate 1 to form a protruding structure, a surface of the auxiliary electrode 6 covering the second bonding portion 5 and close to a second bonding electrode 72 would also form a protruding structure. In this case, when a second bonding electrode 72 may be misalignedly bonded to the second bonding portion 5, the second bonding electrode 72 and the protruding structure on the surface of the auxiliary electrode 6 would be misaligned, causing a part of the surface of the second bonding electrode 72 and the surface of the auxiliary electrode 6 to not fully be fitted and result in gaps. This may reduce the contact area between a second bonding electrode 72 and an auxiliary electrode 6, increasing the resistance between the second bonding electrode 72 and the auxiliary electrode 6. Therefore, a surface of a second bonding portion 5 close to an auxiliary electrode 6 being substantially flush with the second surface 12 of the glass substrate 1 may make the auxiliary electrode 6 covering the second bonding portion 5 flat, ensuring that the auxiliary electrode 6 fully may cover the second bonding electrode 72 even when the second bonding portion 5 may be directly and misalignedly bonded to the second bonding electrode 72, thereby avoiding increased resistance due to reduced contact area.

Specifically, a side of the auxiliary electrode 6 close to the glass substrate 1 may cover the multiple second conductive vias 132 and lap on the glass substrate 1 around the second conductive vias 132. Thus, after the glass substrate 1 and the silicon-based driving substrate 7 may be bonded, part of pressure exerted by a second bonding electrode 72 on the auxiliary electrode 6 may be transferred to the glass substrate 1 through a part of the auxiliary electrode 6 lapping on the glass substrate 1, avoiding a situation in which the auxiliary electrode 6 directly squeezes a second bonding portion 5, which causes the second bonding portion 5 to fall from the second conductive vias 132.

As shown in FIG. 1, in specific embodiments, the silicon-based driving substrate 7 may further include a silicon substrate 73 and a driving circuit layer 74 disposed on the silicon substrate 73. A projection of the driving circuit layer 74 on the silicon substrate 73 along the stacking direction Z may be located within the silicon substrate 73, and the driving circuit layer 74 may cover a part of the surface of the silicon substrate 73 close to the glass substrate 1, and expose a part of the surface of the circumferential edge of the silicon substrate 73. The driving circuit layer 74 may be electrically connected to the multiple first bonding electrodes 71 and the multiple second bonding electrodes 72, respectively, thereby transmitting anode driving signals to the anode electrodes 21 through the first bonding electrodes 71 and cathode driving signals to the cathode electrode 23 through the second bonding electrodes 72. Specifically, the driving circuit layer 74 may include multiple “3TIC” structures (including three thin-film transistors and one capacitor) to achieve independent control and high-quality display of each light-emitting unit 2.

The silicon-based driving substrate 7 may further include a display control circuit (not shown) electrically connected to the driving circuit layer 74. The display control circuit may control the light-emitting units 2 to perform display through the driving circuit layer 74. The display control circuit may be an integrated circuit (IC) integrated on the silicon-based driving substrate 7.

As shown in FIG. 1, the silicon-based driving substrate 7 may further include a protection layer 75 covering a driving circuit layer 74. The protection layer 75 may be used to protect the driving circuit layer 74, so as to avoid external moisture and oxygen intrusion to corrode the circuit traces within the driving circuit layer 74. Specifically, the protection layer 75 may be disposed on a side of the driving circuit layer 74 away from the silicon substrate 73 and lap on a surface of the silicon substrate 73 not covered by the driving circuit layer 74, enabling the protection layer 75 to fully encapsulate the driving circuit layer 74 and isolate it from external moisture and oxygen. In some embodiments, the silicon-based driving substrate 7 may include a silicon substrate 73, a driving circuit layer 74 stacked on the silicon substrate 1, and a protection layer 75 stacked on covering the driving circuit layer 74. The corresponding second bonding electrode 72 may extend from a surface at which of the driving circuit layer 74 and the protection layer 75 may be stacked beyond the protection layer 75 in the stacking direction. The corresponding first bonding electrode 71 may extends from the surface at which of the driving circuit layer 74 and the protection layer 75 may be stacked to a surface of the protection layer 75. Thus, the corresponding first bonding electrode 71 may have a surface flush with the surface of the protection layer 75.

A protection layer 75 further may include multiple first vias 751, and both the first bonding electrodes 71 and the second bonding electrodes 72 may be embedded in the first vias 751 and electrically connected to the driving circuit layer 74. Specifically, the multiple first vias 751 may be arranged in one-to-one correspondence with the multiple first conductive vias 131 and second conductive vias 132, and each first via 751 may penetrate through a protection layer 75 along the stacking direction Z. The first bonding electrodes 71 may be disposed in a part of the first vias 751 corresponding to the first conductive vias 131 to electrically connect the driving circuit layer 74 to the first bonding portions 4. The second bonding electrodes 72 may be disposed in a part of the first vias 751 corresponding to the second conductive vias 132 to electrically connect the driving circuit layer 74 to the conductive adhesive layer. Specifically, the material of the protection layer 75 may be inorganic insulating materials such as silicon dioxide, silicon nitride, or silicon oxynitride.

As shown in FIG. 1, further, an insulating layer 8 may cover the second surface 12 of the glass substrate 1, which may be used to protect the first bonding portions 4, the second bonding portions 5, and a conductive adhesive layer, avoid bonding failure caused by corrosion of the metal due to external moisture and oxygen. A surface of the insulating layer 8 away from the glass substrate 1 may abut against a surface of the protection layer 75 away from the silicon substrate 73. The insulating layer 8 may have second vias 81 at positions corresponding to the first conductive vias 131, and the second vias 81 may penetrate through the insulating layer 8 along the stacking direction Z. The first bonding portions 4 may be embedded in the second vias 81. Specifically, a part of a first bonding portion 4 close to a anode electrode 21 may be embedded in a first conductive via 131 and contact with the anode electrode 21, while a part of the first bonding portion 4 close to the first bonding electrode 71 may be embedded in a portion of the second via 81 corresponding to the first conductive via 131 and contact with the first bonding electrode 71, thereby electrically connecting the first bonding electrodes 71 to the anode electrodes 21.

The insulating layer 8 further may have third vias 82 at positions corresponding to the second conductive vias 132. The third vias 82 may penetrate through the insulating layer 8 along the stacking direction Z, allowing the second bonding portions 5 disposed within the second conductive vias 132 to be exposed through the third vias 82, and the auxiliary electrodes 6 may be embedded in the third vias 82. Specifically, a surface of the second bonding portions 5 away from the glass substrate 1 and part of a surface around the second conductive vias 132 may be exposed through the third vias 82 and covered by an auxiliary electrode 6, thereby electrically connecting the auxiliary electrode 6 to the second bonding portion 5; Moreover, at least part of the surface of the auxiliary electrode 6 away from the glass substrate 1 may be exposed through the third via 82 to facilitate electrical connection with the second bonding electrode 72.

As shown in FIG. 1, in specific embodiments, a surface of the first bonding electrodes 71 away from the silicon substrate 73 may be substantially flush with a surface of the protection layer 75 away from the silicon substrate 73, and a surface of the first bonding portions 4 away from the glass substrate 1 may be substantially flush with a surface of the insulating layer 8 away from the glass substrate 1. Thus, after the first bonding electrodes 71 may be bonded to the first bonding portions 4, the surface of the protection layer 75 away from the silicon substrate 73 may be fitted to the surface of the insulating layer 8 away from the glass substrate 1, thereby avoiding a situation in which corrosion occurs as external moisture and oxygen may be infiltrated through any gap between the protection layer 75 and the insulating layer 8. Specifically, a height of a first bonding electrode 71 along the stacking direction Z may equal to a thickness of a protection layer 75 along the stacking direction Z, and a height of a first bonding portion 4 along the stacking direction Z may equal to a thickness of an insulating layer 8 along the stacking direction Z.

As shown in FIG. 5a and FIG. 5b, further, a surface of the auxiliary electrode 6 away from the glass substrate 1 may be lower than a surface of the insulating layer 8 away from the glass substrate 1, causing the auxiliary electrode 6 and a third via 82 to form a recessed portion 83. A surface of a second bonding electrode 72 away from a silicon substrate 73 may protrude from a surface of a protection layer 75 away from the silicon substrate 73, causing a portion of the second 30) bonding electrode 72 protruding from the protection layer 75 to form a protruding portion 721. When an auxiliary electrode 6 may be bonded to a second bonding electrode 72, a protruding portion 721 may be embedded in a recessed portion 83 to achieve alignment. Therefore, it may play an inducing role during alignment, improve alignment accuracy, and limit a position of the second bonding electrode 72 to prevent issues such as displacement after alignment.

Specifically, a height of the auxiliary electrode 6 along the stacking direction Z may be less than a depth of a third via 82 along the stacking direction Z. A surface of the auxiliary electrode 6 away from the glass substrate 1 may form a bottom wall of a recessed portion 83, and a part of an insulating layer 8 in a third via 82 and away from the glass substrate 1 may form a sidewall of the recessed portion 83. A height of a second bonding electrode 72 along the stacking direction Z may be greater than a depth of a first via 751 along the stacking direction Z.

As shown in FIG. 1, in specific embodiments, an encapsulation layer 24 may be further arranged on the glass substrate 1, which may be used for protecting the light-emitting units 2 on the glass substrate 1 and isolating external moisture and oxygen to prevent failure of the light-emitting units 2 due to the intrusion of moisture and oxygen. Specifically, an encapsulation layer 24 may cover a surface of the cathode electrodes 23 away from the anode electrodes 21 and lap on a surface of the glass substrate 1 which may be not covered by the light-emitting units 2.

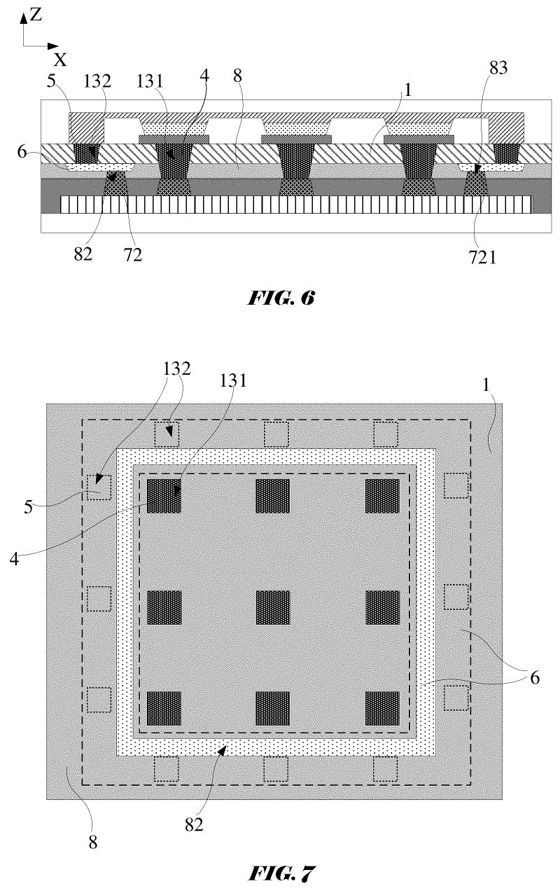

As shown in FIG. 6-FIG. 7, FIG. 6 is a schematic structural view of a display panel according to second embodiments of the present disclosure, and FIG. 7 is a bottom view of the display panel shown in FIG. 6 without the silicon-based driving substrate. A specific structure of the display panel in the second embodiments may be substantially the same as that in the first embodiments of the present disclosure, except that in the second embodiments, the third vias 82 may be misaligned with the second conductive vias 132, so that a pressure exerted by the second bonding electrodes 72 on the auxiliary electrode 6 disposed in the third vias 82 to be further transferred to the glass substrate 1 through the auxiliary electrode 6, thereby further reducing the 20) pressure exerted by the auxiliary electrode 6 on the second bonding portions 5 in the second conductive vias 132 and avoiding the occurrence of the situation where the second bonding portions 5 fall from the second conductive vias 132.

Specifically, As shown in FIG. 6 and FIG. 7, the third vias 82 may be completely misaligned with the second conductive vias 132. A projection of the third vias 82 on the glass substrate 1 along the stacking direction Z may be not overlapped with a projection of the second conductive vias 132 on the glass substrate 1 along the stacking direction Z. The third vias 82 may be annular and located on one side of the second conductive vias 132 along a width direction X of the auxiliary electrode 6. The annular auxiliary electrode 6 may cover the second bonding portions and extends toward the third vias 82 along the width direction X, and thus, a portion of the auxiliary electrode 6 closing to the third vias 82 may be exposed through the third vias 82. It should be understood that the recessed portions 83 may be formed by the annular auxiliary electrode 6 and the third vias 82 may be also misaligned with the second bonding portions 5 in the second conductive vias 132. After the protruding portions 721 of the second bonding electrodes 72 may be embedded in the recessed portions 83, the second bonding electrodes 72 may be also misaligned with the second bonding portions 5, allowing a pressure exerted by the second bonding electrodes 72 on the annular auxiliary electrode 6 to directly act on the glass substrate 1 corresponding to the second bonding electrodes 72 as much as possible. Thus, this protects the second bonding portions from direct compression and avoids the occurrence of the situation where the second bonding portions 5 fall from the second conductive vias 132. In some embodiments, each of the at least one second bonding electrode 72 and a corresponding second bonding portion of the second bonding portions 5 may be located in different lines of a stacking direction X in which the glass substrate 1 and the silicon-based driving substrate 7 may be stacked, such that the at least one second bonding electrode 5 may be misaligned and bonded to the second bonding portions 5 through the auxiliary electrode 6.

In these embodiments, the third vias 82 may be located at an inner side of the second conductive vias 132 along the width direction X. In another embodiments, the third vias 82 may also be located at an outer side of the second conductive vias 132 along the width direction X.

As shown in FIG. 8, which is a bottom view of a display panel without the silicon-based driving substrate according to another embodiments, there may also be multiple second bonding electrodes 72. The second bonding electrodes 72 may be spaced apart from each other around the multiple first bonding electrodes 71. Correspondingly, there may be also multiple third vias 82 on the insulating layer 8, which may be the same with the number of second bonding electrodes 72. Along a circumferential direction of the annular auxiliary electrode 6, the multiple third vias 82 may be alternately spaced apart from multiple second conductive vias 132. A projection of the 20) third vias 82 along the stacking direction Z on the glass substrate 1 may be not overlapped with a projection of the second conductive vias 132 along the stacking direction Z.

This ensures that the multiple second bonding electrodes 72 embedded in the multiple third vias 82 may be misaligned with the multiple second bonding portions 5 in the multiple second conductive vias 132, thereby protecting the second bonding portions 5 from direct compression and avoiding the occurrence of the situation where the second bonding portions 5 fall from the second conductive vias 132, and further reducing the width of the auxiliary electrode 6 to lower preparing costs and helping to reduce the size of the display panel.

The present disclosure provides a display panel, the display panel may include a glass substrate 1, multiple light-emitting units 2, multiple first bonding portions 4, multiple second bonding portions 5, an auxiliary electrode 6, and a silicon-based driving substrate 7. The glass substrate 1 may include a first surface 11 and a second surface 12 opposite to each other. The glass substrate 1 may include multiple conductive vias13 extending from the first surface11 to the second surface12. The multiple conductive vias 13 may include multiple first conductive vias 131 and multiple second conductive vias132. The multiple light-emitting units 2 may be disposed on the first surface 11 of the glass substrate 1. Each of the light-emitting units 2 may include an anode electrode 21, an organic light-emitting layer 22, and a cathode electrode 23, which sequentially stacked in a direction away from the glass substrate 1. Each of the first bonding portions 4 may be at least partially disposed in a corresponding first conductive via 131. Each of the first bonding portions 4 may be electrically connected to the corresponding anode electrode 21 through the corresponding first conductive via 131. Each of the second bonding portions 5 may be at least partially disposed in a corresponding second conductive via 132. Each of the second bonding portions 5 may be electrically connected to the corresponding cathode electrode 23 through the corresponding second conductive via 132. An auxiliary electrode 6 may be disposed on the second surface 12 of the glass substrate 1, covering the second bonding portions 5 and being in contact with the second bonding portions 5. A silicon-based driving substrate 7 may be disposed at a side of second surface 12 of the glass substrate 1, and the silicon-based driving substrate 7 may include multiple first bonding electrodes 71 and at least one second bonding electrode 72. The multiple first bonding electrodes 71 may be aligned and bonded to the multiple first bonding portions 5 in one-to-one correspondence. A second bonding electrode 72 may be bonded to an auxiliary electrode 6. As the light-emitting units 2, the first bonding portions 4 and the second bonding portions 5 may be arranged on the two opposing surfaces of the glass substrate 1 respectively, the first bonding portions 4 may be contacted with and electrically connected with the anode electrodes 21 of the corresponding light-emitting units 2 through the first conductive vias 131, and the second bonding portions 5 may be contacted with and electrically connected with the cathode electrodes 20) 23 of the light-emitting units 2 through the second conductive vias 132. Thus, after the first bonding portions 4 and the second bonding portions 5 may be bonded to the first bonding electrodes 71 and the second bonding electrodes 72 of the silicon-based driving substrate 7 respectively, the electrical coupling between the light-emitting units 2 and the silicon-based driving substrate 7 may be realized, enabling the silicon-based driving substrate 7 to drive the light-emitting units 2 to emit light. In this way, the light-emitting units 2 first may be fabricated on the glass substrate land then bonded to the silicon-based driving substrate7, rather than the light-emitting units 2 being directly fabricated on the silicon-based driving substrate 7, thereby avoiding the problem of damaging to pixel driving circuits and then resulting in a reduction in the product yield which may be caused by directly fabricating the light-emitting units 2 on the silicon-based driving substrate 7. Furthermore, as an auxiliary electrode 6 may be arranged on the second surface 12 of the glass substrate 1 and the second bonding portions 5 may be electrically connected to the second bonding electrodes 72, more current channels may be provided, thereby reducing a resistance between the second bonding portions 5 and the second bonding electrodes 72, effectively decreasing cathode signal load, and consequently reducing cathode signal delay.

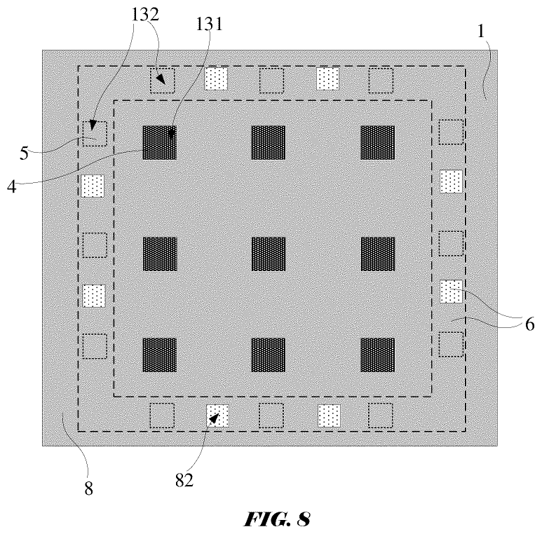

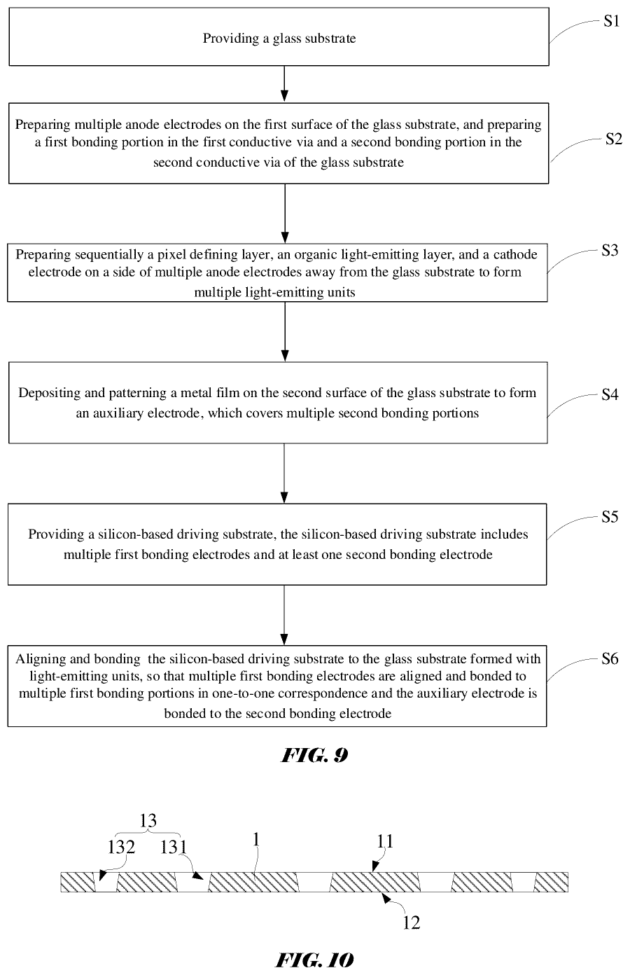

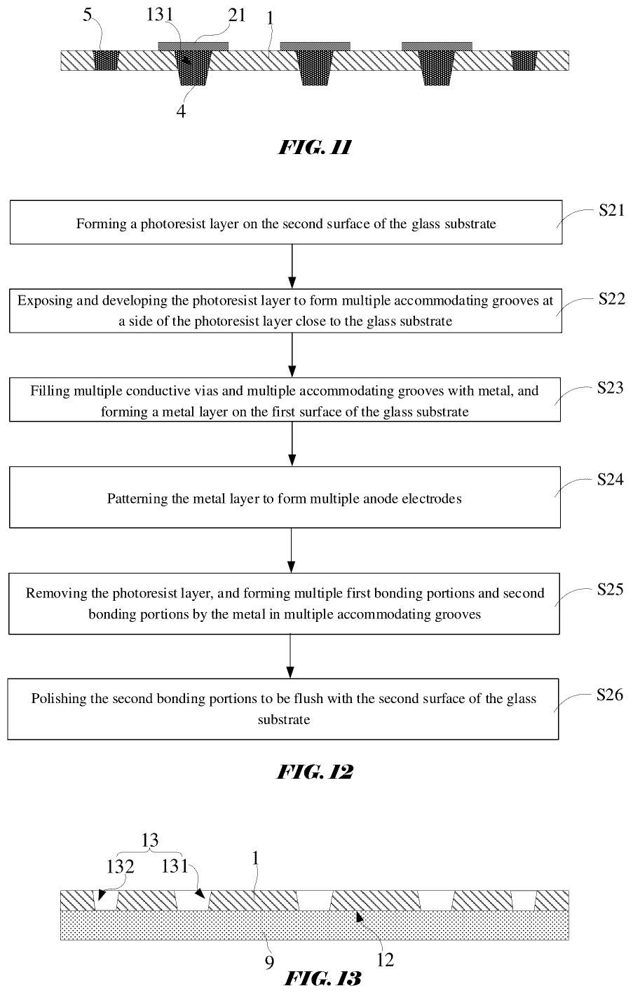

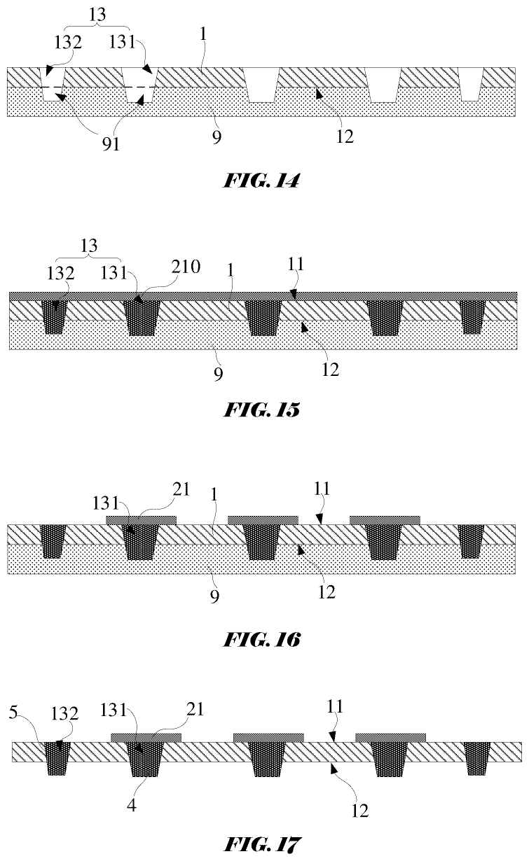

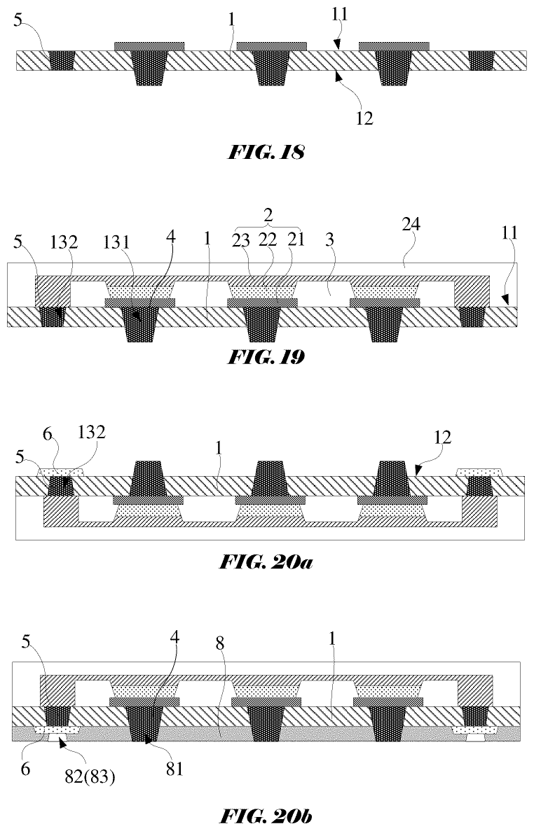

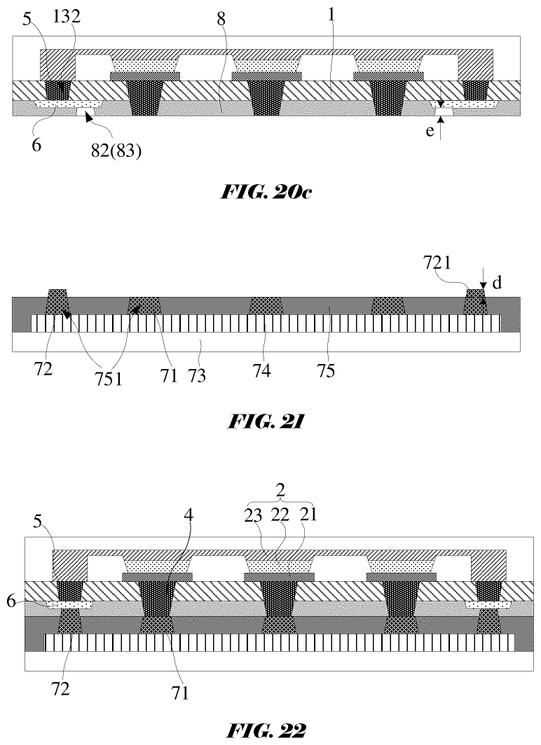

As shown in FIG. 9-FIG. 22, FIG. 9 is a schematic flow chart of a preparing method for a display panel according to embodiments of the present disclosure, FIG. 10 is a schematic structural view after operation S1 is performed, FIG. 11 is a schematic structural view after operation S2 is performed, FIG. 12 is a specific flow chart of operation S2, FIG. 13 is a schematic structural view after operation S21 is performed, FIG. 14 is a schematic structural view after operation S22 is performed, FIG. 15 is a schematic structural view after operation S23 is performed, FIG. 16 is a schematic structural view after operation S24 is performed, FIG. 17 is a schematic structural view after operation S25 is performed, FIG. 18 is a schematic structural view after operation S26 is performed, FIG. 19 is a schematic structural view after operation S3 is performed, FIG. 20a is a schematic structural view after operation S4 is performed, FIG. 20b is a schematic structural view of which an insulating layer is disposed on the structure shown in FIG. 20a, FIG. 20c is a schematic structural view of which an insulating layer is disposed on the second surface according to another embodiments, FIG. 21 is a schematic structural view after operation S5 is performed, FIG. 22 is a schematic structural view after operation S6 is performed. In these embodiments, a preparing method for a display panel is provided, which may be used to prepare the display panel involved in any of the aforementioned embodiments. As shown in FIG. 9, the preparing method may specifically include the following.

At operation S1, the method provides a glass substrate.

Specifically, as shown in FIG. 10, the glass substrate 1 may include a first surface 11 and a second surface 12 opposite to each other. The first surface 11 may be located at a light-emitting side of the display panel, and the opposite surface may be the second surface 12. The glass substrate 1 may include multiple conductive vias 13 extending from the first surface 11 to the second surface 12. In specific implementations, laser-induced etching technology may be employed to form the conductive vias 13 on the glass substrate 1, with a diameter of a conductive via 13 ranging between 50 micrometers and 100 micrometers. The multiple conductive vias 13 may include multiple first conductive vias 131 and multiple second conductive vias 132.

Specifically, the modified region may be first formed as a location where a via may be needed on the glass substrate 1 may be irradiated with laser, and then conductive vias 13 may be formed as the modified regions may be etched with etching solution. By using glass substrate 1, compared to monocrystalline silicon substrate 73, since glass substrate 1 may have better insulation performance, neither is there a need to produce an oxide insulation layer 8 at the via wall of the conductive vias 13, nor is there a need for specialized thin wafer holding technology. Thus, this may reduce costs. At the same time, due to good insulation performance of glass substrate 1, electromagnetic coupling effects may be not easily generated during signal transmission, which may effectively reduce signal insertion loss, crosstalk and other problems, ensuring the integrity of the signal.

At operation S2, the method prepares multiple anode electrodes on the first surface of the glass substrate, and prepares a first bonding portion in the first conductive via and a second bonding portion in the second conductive via of the glass substrate.

Specifically, as shown in FIG. 11, multiple first bonding portions 4 may be arranged with multiple first conductive vias 131 in one-to-one correspondence, and each first bonding portion 4 may be electrically connected to a corresponding anode electrode 21 through a corresponding first conductive via 131. An anode electrode 21 may be used to transmit an anode driving signal to an organic light-emitting layer 22 to drive the organic light-emitting layer 22 to emit light. The first bonding portions 4 may be used for subsequent alignment bonding with the first bonding electrodes 71 of the silicon-based driving substrate 7, so that the anode driving signal may be transmitted to the anode electrodes 21 through the first bonding portions 4. Specifically, the first bonding portions 4 may extend along the first conductive vias 131 to be in contact with the anode electrodes 21. As shown in FIG. 12, in the specific implementations, what at operation S2 may specifically include the following.

At operation S21, the method forms a photoresist layer on the second surface of the glass substrate.

Specifically, as shown in FIG. 13, a photoresist layer 9 may be coated on the second surface 12 of the glass substrate 1, and the photoresist layer 9 may cover multiple conductive vias 13.

At operation S22, the method exposes and develops the photoresist layer to form multiple accommodating grooves at a side of the photoresist layer close to the glass substrate.

Specifically, as shown in FIG. 14, a portion of the photoresist layer 9 exposed through the conductive vias 13 may be exposed and developed from the first surface 11 of the glass substrate 1, so as to form multiple accommodating grooves 91 which may be in one-to-one correspondence and communicated with the multiple conductive vias 13, for preparing the first bonding portions 4 and the second bonding portions 5.

At operation S23, the method fills multiple conductive vias and multiple accommodating grooves with metal, and forms a metal layer on the first surface of the glass substrate.

Specifically, as shown in FIG. 15, metal material may be deposited from one side of the first surface 11 of the glass substrate 1 into multiple conductive vias 13 and corresponding multiple accommodating grooves 91, and metal material may be deposited on the first surface 11 of the glass substrate 1 to form a metal layer 210. The metal layer 210 may cover multiple conductive vias 13.

At operation S24, the method patterns the metal layer to form multiple anode electrodes.

Specifically, as shown in FIG. 16, the metal layer 210 on the first surface 11 may be patterned by mask etching, while a portion of the metal layer 210 corresponding to multiple first conductive vias 131 may be retained, such that multiple spaced anode electrodes 21 may be formed. A projection of the first conductive via 131 on the glass substrate 1 along the stacking direction may be located within a projection of a corresponding anode electrode 21 on the glass substrate 1 along the stacking direction. That is, an anode electrode 21 completely may cover the first conductive vias 131.

At operation S25, the method removes the photoresist layer, and forms multiple first bonding portions and second bonding portions by the metal in multiple accommodating grooves. Specifically, as shown in FIG. 17, the photoresist layer 9 on the second surface 12 of the glass substrate 1 may be removed by exposure, so as to expose the metal in multiple accommodating grooves 91 and form multiple first bonding portions 4 and multiple second bonding portions 5. The first bonding portions 4 may be located in the first conductive vias 131. The first bonding portions 4 may extend along the first conductive vias 131 from the surface of the anode electrodes 21 towards the glass substrate 1 to the second surface 12 of the glass substrate 1, and protrude from the second surface 12. The second bonding portions 5 may be located within the second conductive vias 132. The second bonding portions 5 may extend from the first surface 11 of the glass substrate 1 along the second conductive vias 132 to the second surface 12, and protrude from the second surface 12.

At operation S26, the method polishes the second bonding portions to be flush with the second surface of the glass substrate.

Specifically, as shown in FIG. 18, the second bonding portions 5 may be polished to remove the portion of the second bonding portions 5 protruding from the second surface 12 of the glass substrate 1, so that surfaces of the second bonding portions 5 away from the first surface 11 may be substantially flush with the second surface 12 of the glass substrate 1. Thus, this facilitates bonding between the auxiliary cathode and the second bonding portions 5, and avoids a situation in which the second bonding portions 5 is squeezed to fall after the glass substrate 1 and the silicon-based driving substrate 7 may be bonded.

At operation S3, the method sequentially prepares a pixel defining layer, an organic light-emitting layer, and a cathode electrode on a side of multiple anode electrodes away from the glass substrate to form multiple light-emitting units.

Specifically, as shown in FIG. 19, the pixel defining layer 3 may be patterned on the first surface 11 of the glass substrate 1 using photoresist, or may be patterned on an inorganic material film layer, depending on actual needs. Pixel defining layer 3 may protrude from glass substrate 1 and enclose to form multiple pixel accommodation regions. The pixel defining layer 3 may cover edges of the anode electrodes 21 to ensure that adjacent anode electrodes 21 do not be contacted. A surface of the anode electrodes 21 may be partially exposed through the pixel accommodation region to prepare an organic light-emitting layer 22 on the surface of the anode electrodes 21 located within the pixel accommodation region.

Different light-emitting layer materials may be used to evaporate and form organic light-emitting layers 22 with different light-emitting colors on surfaces of multiple anode electrodes 21, such as red light-emitting layer, green light-emitting layer, and blue light-emitting layer. In some embodiments, white light-emitting layer material may be used for vapor deposition to form a white light-emitting layer. Subsequently, a color filter layer may be fabricated to achieve color display.

In specific implementations, cathode material may be deposited on a side of the organic light-emitting layers 22 away from the glass substrate 1 by evaporation or sputtering to form the cathode electrodes 23. Specifically, the cathode material may be deposited on each of organic light-emitting layers 22 and pixel defining layers 3 and extended to be deposited on the second conductive vias 132, and an electrical connection may be formed as the second bonding portions and the second conductive vias 132 may be contacted. Thus, a complete cathode electrode 23 may be formed to improve the uniformity of the cathode driving signal and reduce voltage drop. In some embodiments, multiple second conductive vias 132 may be arranged around multiple first conductive vias 131 to further improve the uniformity of the cathode driving signal.

Further, after the operation of preparing the cathode electrode 23, the method may further include preparing an encapsulation layer on the side of the cathode electrode away from the glass substrate to encapsulate the light-emitting unit.

Specifically, the encapsulation layer 24 may be a multi-layer stack of organic encapsulation layers and inorganic encapsulation layers to ensure encapsulation effectiveness and isolate external moisture and oxygen to prevent moisture and oxygen from be invaded and cause the failure of the light-emitting units 2.

At operation S4, the method deposits and patterns a metal film on the second surface of the glass substrate to form an auxiliary electrode, which may cover multiple second bonding portions.

Specifically, as shown in FIG. 20a, chemical vapor deposition (CVD) or physical vapor deposition (PVD) methods may be used to deposit metal materials on the second surface 12 of the glass substrate 1 to form a metal film (not shown in the FIG.), and the metal film may be patterned by mask etching to retain a portion of the metal film corresponding to multiple second conductive vias 132. Thus, an annular auxiliary electrode 6 may be formed. The annular auxiliary electrode 6 may cover multiple second bonding portions 5 to provide more current channels, thereby reducing a resistance between the second bonding portions 5 and the second bonding electrodes 72, effectively reducing the cathode signal load and thus reducing the cathode signal delay. Specifically, metal material may be deposited on the second surface 12 using magnetron sputtering.

Specifically, along the width direction X, both sides of the auxiliary electrode 6 may be lapped on the second surface 12 of the glass substrate 1. Thus, after the glass substrate 1 and the silicon-based driving substrate 7 may be bonded, a part of pressure exerted by a second bonding electrode 72 on the auxiliary electrode 6 may be transferred to the glass substrate 1 through a part of the auxiliary electrode 6 lapping on the glass substrate 1, avoiding a situation in which the auxiliary electrode 6 directly squeezes a second bonding portion 5, which causes the second bonding portion 5 to fall from the second conductive vias 132.

After operation S4, the method may further include depositing an insulating layer on the second surface of the glass substrate, and arranging second vias and third vias on the insulating layer.

Specifically, as shown in FIG. 20b, the second vias 81 may be formed at a position corresponding to the first bonding portions 4 on the insulation layer 8, so that the first bonding portions 4 may be exposed through the second vias 81. The third vias 82 may be formed at a position corresponding to the second bonding portions 5 on the insulating layer 8, so that the second bonding portions 5 may be exposed through the third vias 82.

A surface of an auxiliary electrode 6 away from the glass substrate 1 may be lower than a surface of an insulating layer 8 away from the glass substrate 1, so that the auxiliary electrode 6 and the third vias 82 form the recessed portions 83, which may play an induction role during alignment and improve alignment accuracy.

Of course, in other embodiments, as shown in FIG. 20c, a third via 82 formed on the insulating layer 8 may also be misaligned with a second conductive via 132, so that the pressure exerted by a second bonding electrode 72 on the auxiliary electrode 6 in the third via 82 may be further transferred to the glass substrate 1 through the auxiliary electrode 6, thereby further reducing the pressure of the auxiliary electrode 6 on the second bonding portion 5 in the second conductive vias 132, and avoiding the occurrence of the situation where the second bonding portions 5 fall from the second conductive vias 132.

At operation S5, the method provides a silicon-based driving substrate. The silicon-based driving substrate includes multiple first bonding electrodes and at least one second bonding electrode.

Specifically, as shown in FIG. 21, as a driving circuit layer 74 may be fabricated on a silicon substrate 73 and thus the light-emitting units 2 and the silicon-based driving substrate 7 may be separately prepared, not only may production efficiency be improved, but also may the advantages of a silicon-based driving substrate 7 be retained by using a silicon substrate 73 as the substrate for the silicon-based driving substrate 7. At the same time, as the glass substrate 1 may be used as the substrate for the light-emitting units 2, cost may be saved, and the glass substrate 1 may have better stability and may be less susceptible to deformation due to temperature, which is beneficial for maintaining the stability and electrical performance of the light-emitting device. The glass substrate 1 may have better transparency, which is beneficial for improving the brightness of the display panel.

Conductive material may be deposited and patterned on a surface of the driving circuit layer 74 away from the silicon substrate 73 to form multiple first bonding electrodes 71 and at least one second bonding electrode 72. Each of the first bonding electrodes 71 and the second bonding electrodes 72 may be electrically connected to the driving circuit layer 74, so that the driving circuit layer 74 may transmit the anode driving signal through the first bonding electrodes 71 and the cathode driving signal through the second bonding electrodes 72.

Insulating material may be deposited on a surface of the driving circuit layer 74 away from the silicon substrate 73 to form a protection layer 75 for protecting the driving circuit layer 74. The first vias 751 may be formed at a position respectively corresponding to the first bonding electrodes 71 and the second bonding electrodes 72 on the protection layer 75, so that the first bonding electrodes 71 and the second bonding electrodes 72 may be exposed through the first vias 751. That is, the first bonding electrodes 71 and the second bonding electrodes 72 may be respectively embedded in the first vias 751.

A surface of the second bonding electrode 72 away from the silicon substrate 73 may protrude from a surface of the protection layer 75 away from the silicon substrate 73, so that portions of the second bonding electrodes 72 protruding from the protection layer 75 may form the protruding portions 721. A height d of the protruding portion 721 may be greater than a depth e of the recessed portion 83. For example, the height d of the protruding portion 721 may be 5%-10% greater than the depth e of the recessed portion 83.

At operation S6, the method aligns and bonds the silicon-based driving substrate to the glass substrate formed with light-emitting units, so that multiple first bonding electrodes may be aligned and bonded to multiple first bonding portions in one-to-one correspondence and the auxiliary electrode is bonded to the second bonding electrode.

Specifically, as shown in FIG. 22, as multiple first bonding electrodes 71 may be aligned and bonded to multiple first bonding portions 4 in one-to-one correspondence, the anode driving signal of the silicon-based driving substrate 7 may be transmitted to the anode electrodes 21 of the light-emitting units 2 through the first bonding electrodes 71 and the first bonding portions 4. As an auxiliary electrode 6 may be bonded to the second bonding electrodes 72, the cathode driving signal of the silicon-based driving substrate 7 may be transmitted to the cathode electrodes 23 of the light-emitting units 2 through the second bonding electrodes 72, the auxiliary electrode 6, and the second bonding portions 5, and then an organic light-emitting layer 22 may be drove to emit light.

Specifically, what at operation S6 may also include: embedding the protruding portion into the recessed portion, such that a height of the protruding portion may be compressed to be equal to a depth of the recessed portion.

As shown in FIG. 20C and FIG. 21, when an auxiliary electrode 6 may be bonded to the second bonding electrodes 72, the protruding portions 721 may be embedded in the recessed portions 83 to form alignment. Thus, this may play an inducing role in alignment, improve alignment accuracy, and limit the second bonding electrodes 72 to avoid displacement and other problems after alignment. A height of the protruding portions 721 may be compressed to make the bonding between the second bonding electrodes 72 and an auxiliary electrode 6 tighter, so as to increase an effective contact area between the second bonding electrodes 72 and the auxiliary electrode 6, and further reduce the resistance.

It may be understood that the compressed second bonding electrodes 72 will exert a large pressure on the auxiliary electrode 6. As the third vias 82 may be misaligned with the second conductive vias 132, the pressure exerted by the second bonding electrodes 72 on the auxiliary electrode 6 may be transferred to the glass substrate 1 through the auxiliary electrode 6, thereby further reducing the pressure of the auxiliary electrode 6 on the second bonding portions 5, and avoiding the occurrence of the situation where the second bonding portions 5 fall from the second conductive vias 132.

The present disclosure provides a method for preparing a display panel, which includes: first providing a glass substrate 1. Thus, multiple anode electrodes 21 may be prepared on the first surface 11 of the glass substrate 1. Each of the first bonding portions 4 may be prepared in the first conductive via 131 of the glass substrate 1, and each of the second bonding portions 5 may be prepared in the second conductive via 132 of the glass substrate 1. Next, a pixel defining layer 3, an organic light-emitting layer 22, and a cathode electrode 23 may be sequentially prepared on a side of multiple anode electrodes 21 away from the glass substrate 1 to form multiple light-emitting units 2. Then, a metal film may be deposited on the second surface 12 of the glass substrate 1 and patterned to form an auxiliary electrode 6, so that the auxiliary electrode 6 may cover multiple second bonding portions 5. Then a silicon-based driver substrate 7 may be provided. the silicon-based driving substrate 7 may include multiple first bonding electrodes 71 and at least one second bonding electrode 72. Finally, the silicon-based driving substrate 7 may be aligned and bonded with the glass substrate 1 formed with the light-emitting units 2, so that multiple first bonding electrodes 71 may be aligned and bonded with multiple first bonding portions 4 in a one-to-one correspondence, and the auxiliary electrode 6 may be bond with the second bonding electrodes 72. In this preparation method, the light-emitting units 2 first may be fabricated on the glass substrate land then bonded to the silicon-based driving substrate7, rather than the light-emitting units 2 being directly fabricated on the silicon-based driving substrate 7, thereby avoiding the problem of damaging to pixel driving circuits and then resulting in a reduction in the product yield which is caused by directly fabricating the light-emitting units 2 on the silicon-based driving substrate 7. Furthermore, as an auxiliary electrode 6 may be arranged on the second surface 12 of the glass substrate 1 and the second bonding portions 5 may be electrically connected to the second bonding electrodes 72, more current channels may be provided, thereby reducing a resistance between the second bonding portions 5 and the second bonding electrodes 72, effectively decreasing cathode signal load, and consequently reducing cathode signal delay.

The above description are only embodiments of the present disclosure, and do not limit the scope of the present disclosure. Any equivalent structure or equivalent process transformation made by using the contents of the description and drawings of the present disclosure, or directly or indirectly used in other related technical fields, are similarly comprised in the scope of patent protection of the present disclosure.

1. A display panel, comprising:
a glass substrate, comprising a first surface and a second surface opposite to each other and having a plurality of conductive vias extending from the first surface to the second surface; the plurality of conductive vias comprising a plurality of first conductive vias and a plurality of second conductive vias;
a plurality of light-emitting units, disposed on the first surface of the glass substrate; each of the light-emitting units comprising an anode electrode, an organic light-emitting layer, and a cathode electrode sequentially stacked in a direction away from the glass substrate;
a plurality of first bonding portions, each of the first bonding portions being at least partially disposed within a corresponding first conductive via of the first conductive vias and being electrically connected to a corresponding anode electrode through the corresponding first conductive via;
a plurality of second bonding portions, each of the second bonding portions being at least partially disposed within a corresponding second conductive via of the second conductive vias and being electrically connected to a corresponding cathode electrode through the corresponding second conductive via;
an auxiliary electrode, disposed on the second surface of the glass substrate, covering the second bonding portions, and being in contact with the second bonding portions; and
a silicon-based driving substrate, disposed on the second surface of the glass substrate and comprising a plurality of first bonding electrodes and at least one second bonding electrode; the plurality of first bonding electrodes being aligned and bonded to the plurality of first bonding portions in one-to-one correspondence; the at least one second bonding electrode being bonded to the auxiliary electrode.

2. The display panel according to claim 1, wherein the plurality of second conductive vias are spaced apart and disposed around the plurality of first conductive vias; the plurality of second bonding portions are disposed around the plurality of first bonding portions;
the auxiliary electrode is an annular auxiliary electrode disposed around the plurality of first conductive vias; the annular auxiliary electrode covers the plurality of second bonding portions.

3. The display panel according to claim 2, wherein the at least one second bonding electrode is an annular bonding electrode, wherein a width of the annular bonding electrode is less than a width of the annular auxiliary electrode, and the annular auxiliary electrode covers the annular bonding electrode.

4. The display panel according to claim 1, wherein a surface of each of the second bonding portions close to the auxiliary electrode is flush with the second surface of the glass substrate, and the auxiliary electrode covers the plurality of second conductive vias.

5. The display panel according to claim 4, wherein the silicon-based driving substrate comprises:
a silicon substrate,
a driving circuit layer disposed on the silicon substrate, and
a protection layer covering the driving circuit layer and defining via plurality of first vias;
wherein each of the first bonding electrodes and the least one second bonding electrode is embedded in a corresponding first via of the first vias and electrically connected to the driving circuit layer;
an insulating layer covers the second surface of the glass substrate, and the insulating layer comprises a second via at a position corresponding to each of the first conductive vias, wherein a corresponding first bonding portion is embedded in a corresponding second via; the insulating layer further comprises at least one third via, and a corresponding second bonding portion of the least one second bonding portion is exposed through a corresponding third via of the least one third via.

6. The display panel according to claim 5, wherein a surface of the auxiliary electrode away from the glass substrate is lower than a surface of the insulating layer away from the glass substrate in a stacking direction in which the glass substrate and the silicon-based driving substrate are stacked, such that a recessed portion is formed;
a surface of the second bonding electrode away from the silicon substrate protrudes from a surface of the protection layer away from the silicon substrate, such that a protruding portion is formed;
the protruding portion is embedded into the recessed portion.

7. The display panel according to claim 5, wherein a corresponding third via is misaligned with a corresponding second conductive via.

8. A display panel, comprising:
a glass substrate, comprising a plurality of first bonding portions and a plurality of second bonding portions, wherein each of the first bonding portions is electrically connected to a corresponding anode electrode, and each of the second bonding portions is electrically connected to a corresponding cathode electrode;
an auxiliary electrode, being in contact with the second bonding portions; and
a silicon-based driving substrate, aligned and bonded to the glass substrate, wherein the silicon-based driving substrate comprises a plurality of first bonding electrodes and at least one second bonding electrode; the plurality of first bonding electrodes are aligned and bonded to the plurality of first bonding portions in one-to-one correspondence; the at least one second bonding electrode is bonded to the second bonding portions through the auxiliary electrode.

9. The display panel according to claim 8, wherein the first bonding portions are arranged in an array, and the second bonding portions are arranged around the array;
the auxiliary electrode is an annular auxiliary electrode to cover the second bonding portions and be in contact with the second bonding portions.

10. The display panel according to claim 9, wherein every two adjacent one of the first bonding portions in a direction of the array have a same distance, and each of the second bonding portions corresponds to one first bonding portion of the first bonding portions.

11. The display panel according to claim 9, wherein the at least one second bonding electrode is an annular bonding electrode, wherein the annular bonding electrode is covered by the annular auxiliary electrode.

12. The display panel according to claim 11, wherein a size of the annular bonding electrode is less than a size of the annular auxiliary electrode such that the annular bonding electrode is covered by the annular auxiliary electrode.

13. The display panel according to claim 8, wherein a thickness of each of the second bonding portions, a corresponding second bonding electrode, and the auxiliary electrode in a stacking direction in which the glass substrate and the silicon-based driving substrate are stacked is equal to a thickness of each of the first bonding portions and a corresponding first bonding electrode in the stacking direction.

14. The display panel according to claim 13, wherein a thickness of the each of the second bonding portions is less than a thickness of the each of the first bonding portions;
a thickness of the corresponding second bonding electrode is greater than a thickness of the corresponding first bonding electrode.

15. The display panel according to claim 14, wherein the each of the second bonding portions extends from a first surface of the glass substrate to a second surface of the glass substrate in the stacking direction, and the each of the first bonding portions extends from the first surface beyond the second surface in the stacking direction, wherein the first surface is opposite to the second surface.

16. The display panel according to claim 15, wherein a surface of the auxiliary electrode is flush with the second surface of the glass substrate and is in contact with the second bonding portions.

17. The display panel according to claim 14, wherein the silicon-based driving substrate comprises:
a silicon substrate,
a driving circuit layer stacked on the silicon substrate, and
a protection layer stacked on covering the driving circuit layer;
the corresponding second bonding electrode extends from a surface at which of the driving circuit layer and the protection layer are stacked beyond the protection layer in the stacking direction, and the corresponding first bonding electrode extends from the surface at which of the driving circuit layer and the protection layer are stacked to a surface of the protection layer, wherein the corresponding first bonding electrode has a surface flush with the surface of the protection layer.

18. The display panel according to claim 8, wherein each of the at least one second bonding electrode and a corresponding second bonding portion of the second bonding portions are located in a same line of a stacking direction in which the glass substrate and the silicon-based driving substrate are stacked, such that the at least one second bonding electrode is aligned and bonded to the second bonding portions through the auxiliary electrode.

19. The display panel according to claim 8, wherein each of the at least one second bonding electrode and a corresponding second bonding portion of the second bonding portions are located in different lines of a stacking direction in which the glass substrate and the silicon-based driving substrate are stacked, such that the at least one second bonding electrode is misaligned and bonded to the second bonding portions through the auxiliary electrode.

20. A display panel, comprising:
a glass substrate, comprising a plurality of first bonding portions and a plurality of second bonding portions;
a plurality of light-emitting units, disposed on the glass substrate, wherein each of the light-emitting units comprises an anode electrode, an organic light-emitting layer, and a cathode electrode sequentially stacked on the glass substrate, a corresponding anode electrode is electrically connected to a corresponding one of the first bonding portions, and a corresponding cathode electrode is electrically connected to a corresponding one of the second bonding portions;
an auxiliary electrode, being in contact with the second bonding portions; and
a silicon-based driving substrate, aligned and bonded to the glass substrate, wherein the silicon-based driving substrate comprises a plurality of first bonding electrodes and at least one second bonding electrode; the plurality of first bonding electrodes are aligned and bonded to the plurality of first bonding portions in one-to-one correspondence; the at least one second bonding electrode is bonded to the second bonding portions through the auxiliary electrode.
